(19) United States
(12) Patent Application Publication
(10) Pub. No.: US 2010/0070867 A1
(43) Pub. Date: Mar. 18, 2010

(54) NETWORK CONFIGURATION VIA A WIRELESS DEVICE

(75) Inventor: Johannes Hendrikus Maria Lemmers, Reek (NL)

Correspondence Address: PHILIPS INTELLECTUAL PROPERTY & STANDARDS, P. O. Box 3001, BRIARCLIFF MANOR, NY, 10510, US

(73) Assignee: KONINKLIJKE PHILIPS ELECTRONICS N. V., Eindhoven (NL)

(21) Appl. No.: 12/522,921

(22) PCT Filed: Jan. 10, 2008
(86) PCT No.: PCT/IB2008/050085

§ 371 Date: Jul. 13, 2009

Related U.S. Application Data
(60) Provisional application No. 60/885,640, filed on Jan. 19, 2007.

(51) Int. Cl. G06F 15/177; G06F 3/048; G06F 15/16; H03M 13/09; G06F 11/10; H04N 7/167

(52) U.S. Cl. 715/735; 709/222; 709/206; 714/809; 725/31; 714/E11.032

(57) ABSTRACT

When configuring a network system (10) in a user's residence, a patient to receive home healthcare assistance or other user receives an encoded configuration message. One type of configuration message includes a sequence of code words, each of which corresponds to one or more numerical digits, which the user receives via voice or text message on a mobile phone (28), as an email message, etc., and the user enters the codewords into a set top box (STB) (12). The user enters the codewords by selecting the codewords and/or images representing the codewords displayed on a GUI (18). The STB (12) uses a translation table (40, 42) to decode the codewords to determine the numerical sequences. The complete sequence represents a configuration information sequence, such as a user ID, an IP address, or the like, and is employed by the STB (12) to configure itself and/or other components in the network system (10). If the configuration message is received on a Bluetooth-capable cellular device, the configuration sequence is sent wirelessly to the STB (12).

The present application finds particular application in healthcare and wellness systems, particularly involving assisting the elderly or infirm in configuring a remote health monitoring system. However, it will be appreciated that the described technique may also find application in other remote access systems, other user identification and/or system configuration scenarios, or other encoding/decoding techniques.

Complex networking devices that are to be installed at a consumer's home often require complicated configuration, which may differ between users, service providers, countries, etc. This in turn further exacerbates difficulties that may be experienced by users. For example, network configuration and user ID information may vary in different countries that employ different frequencies and/or channels for network service. Such differences complicate creation of a universal off-the-shelf system because devices or components of the system typically require country-specific and/or user-specific factory pre-configuration in order to function properly in a given locale.

Other problems arise when a user has little experience and/or aptitude for configuring a network, let alone setting network security parameters during configuration of the network. Moreover, users of advanced age often have other limitations that can hamper system installation, such as degraded eyesight and/or lack of experience with newer technologies. For example, it can be difficult for a user with poor eyesight to correctly enter an encrypted security key with multiple alphanumeric characters, varied upper- and lower-case characters, etc. Often, repeated mistakes in security key entry can result in user frustration and disregarding of the protocol, which in turn leaves the network connection insecure and vulnerable. Alternatively, such a user may be forced to pay a premium for a professional to make a house call to install the system or occupy a service provider help line for an extended duration in an attempt to identify the problem, both of which add to overall system cost. The present application provides new and improved user identification and network configuration systems and methods, which overcome the above-referenced problems and others.

In accordance with one aspect, a system for configuring a remote healthcare system using encoded configuration messages includes a set top box (STB) into which a user enters encoded configuration information, and a translation table that stores a plurality of codewords and corresponding numerical sequences for decoding the encoded configuration information. The system further includes a graphical user interface (GUI) that presents information related to system configuration to the user.

In accordance with another aspect, a method of configuring a system includes generating a translation table that pairs numerical sequences to codewords, storing the translation table to a set top box (STB), and sending a text message to a user, wherein the text message includes a sequence of codewords. The method further includes prompting the user to enter the sequence of codewords into the STB, decoding the codewords using the translation table to identify respective numerical sequences, and employing the numerical sequences to configure at least one of the STB and the system.

One advantage is that generic off-the-shelf devices can be easily configured in the user's home rather than expensively pre-configured at a factory or service provider.

Another advantage resides in secure distribution of user identification information to mitigate inadvertent user identity confusion or theft.

Another advantage resides in mitigating a need for a user to employ a professional installer, help desk resources, or other expensive assistance.

Yet another advantage relates to ease of use, which facilitates enabling usage by elderly, infirm and/or technology-challenged patients.

Still other advantages reside in the robustness of the described mechanisms, which facilitates error detection and correction.

Still further advantages of the subject innovation will be appreciated by those of ordinary skill in the art upon reading and understand the following detailed description.

The innovation may take form in various components and arrangements of components, and in various steps and arrangements of steps. The drawings are only for purposes of illustrating various aspects and are not to be construed as limiting the invention.

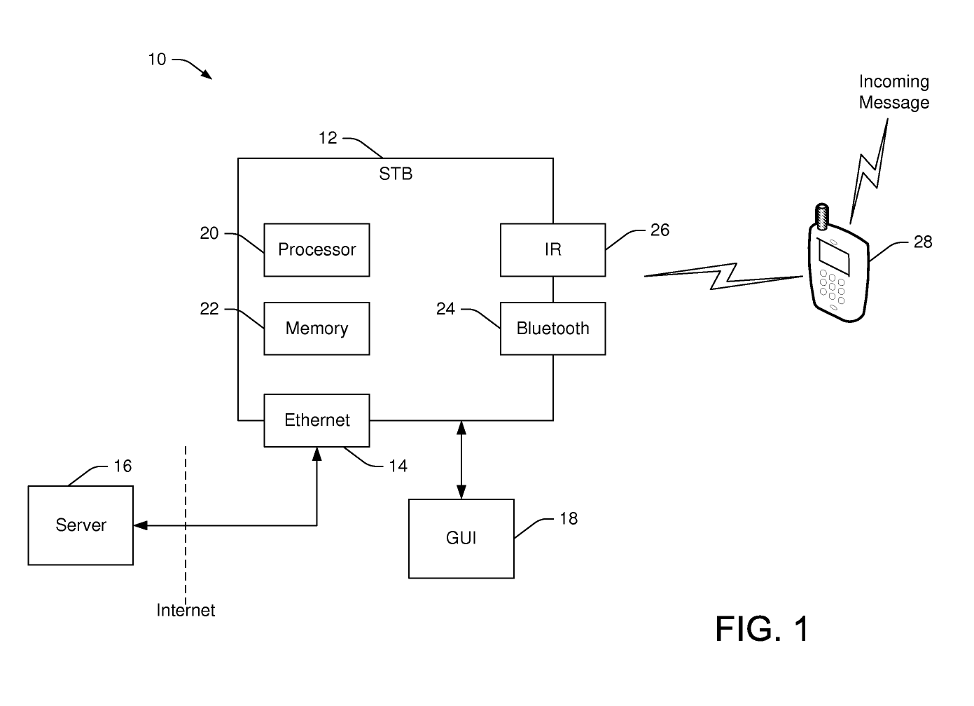

FIG. 1 illustrates a remote care system for configuring an STB in a patient's residence, rather than pre-configuring the STB at the service provider, and for providing a secure, personalized platform service that connects a remotely located patient to his or her care provider.

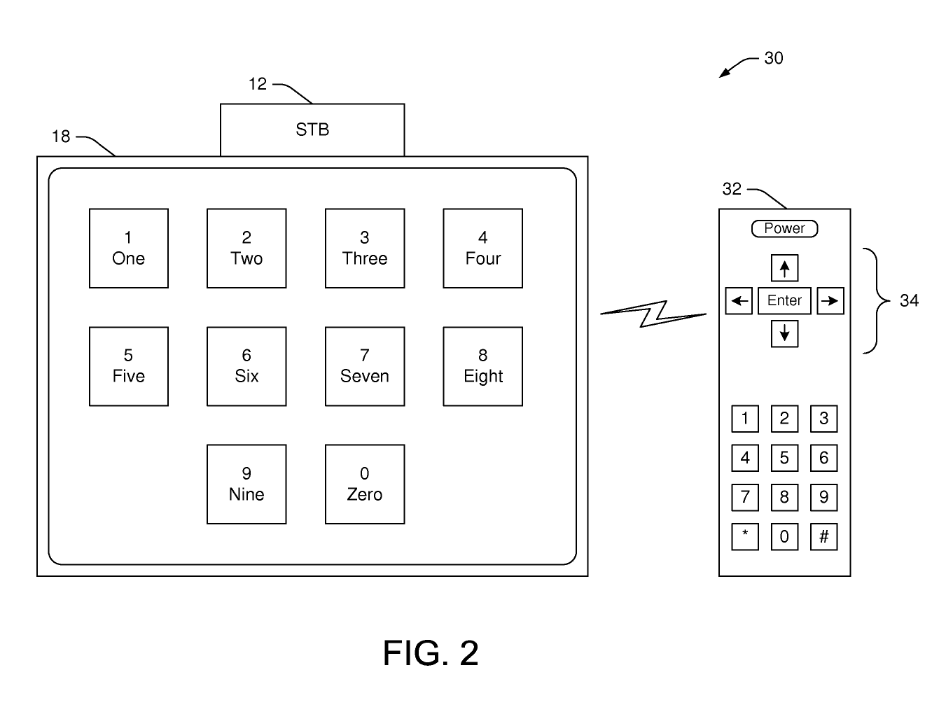

FIG. 2 illustrates a system for entering information received in a message from a service provider into the STB using the GUI and a remote control.

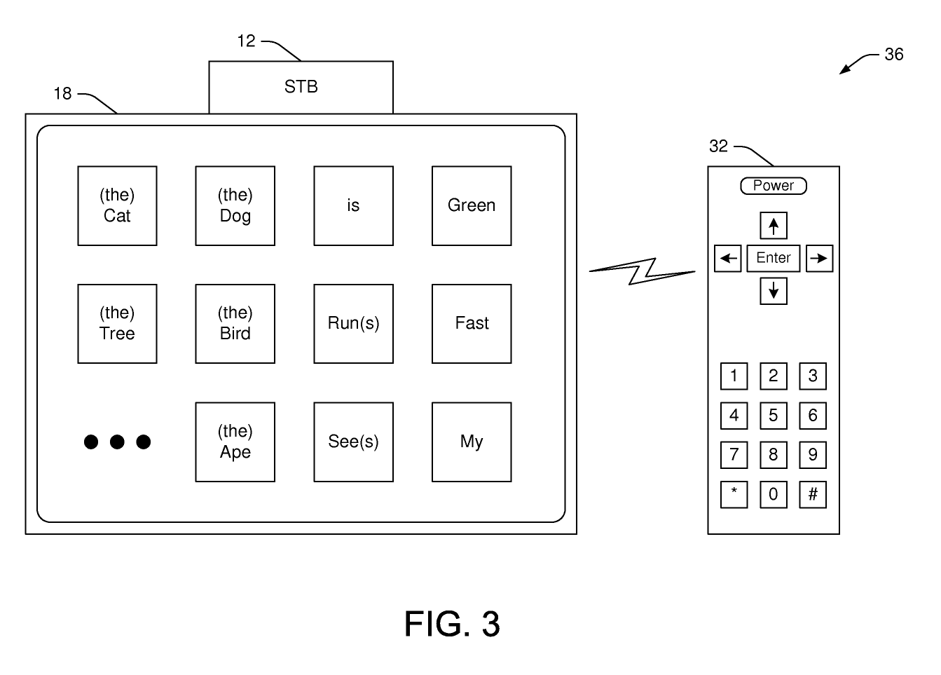

FIG. 3 shows a remote care system for entering received information into the STB using the GUI and a remote control device, wherein codewords are presented on the GUI for user selection.

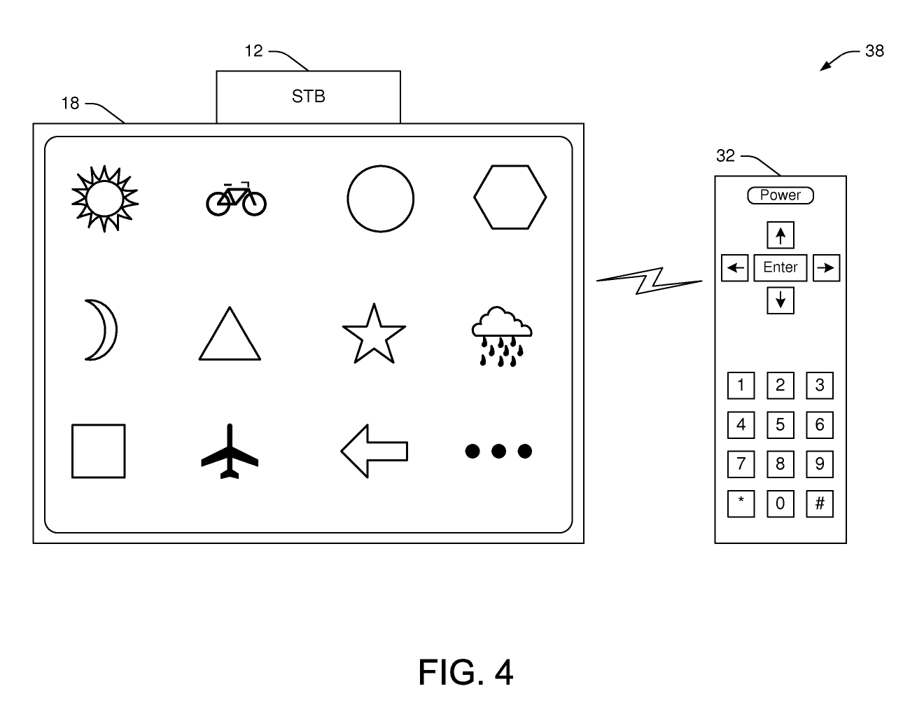

FIG. 4 illustrates a system for configuring the STB using the GUI and a remote control device, wherein codewords are represented by respective symbols on the GUI.

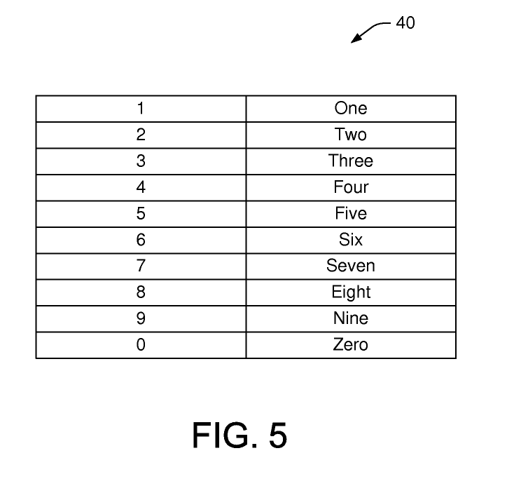

FIG. 5 is an example of a translation table, such as can be utilized to encode messages for a user and/or to decode messages entered and/or forwarded to the STB by the user.

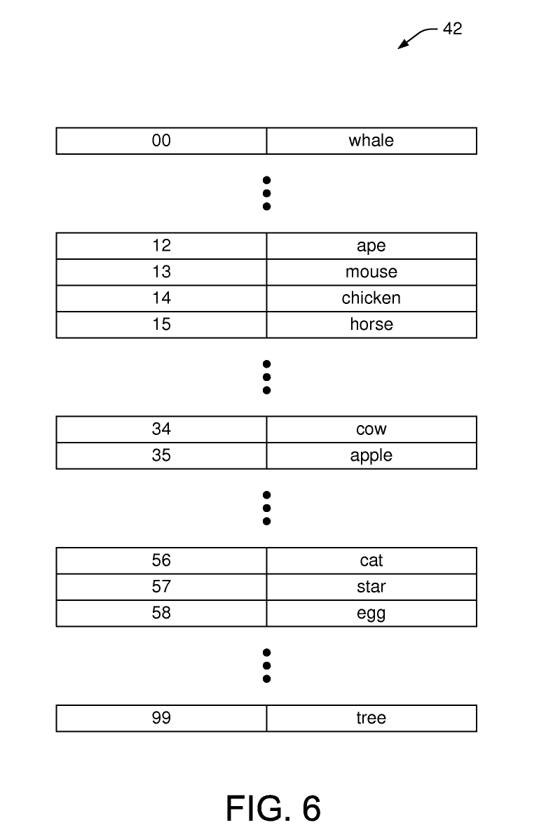

FIG. 6 shows a more complex translation table, which can be utilized as a codec to encode and/or decode messages by identifying codewords and their corresponding numerical sequences.

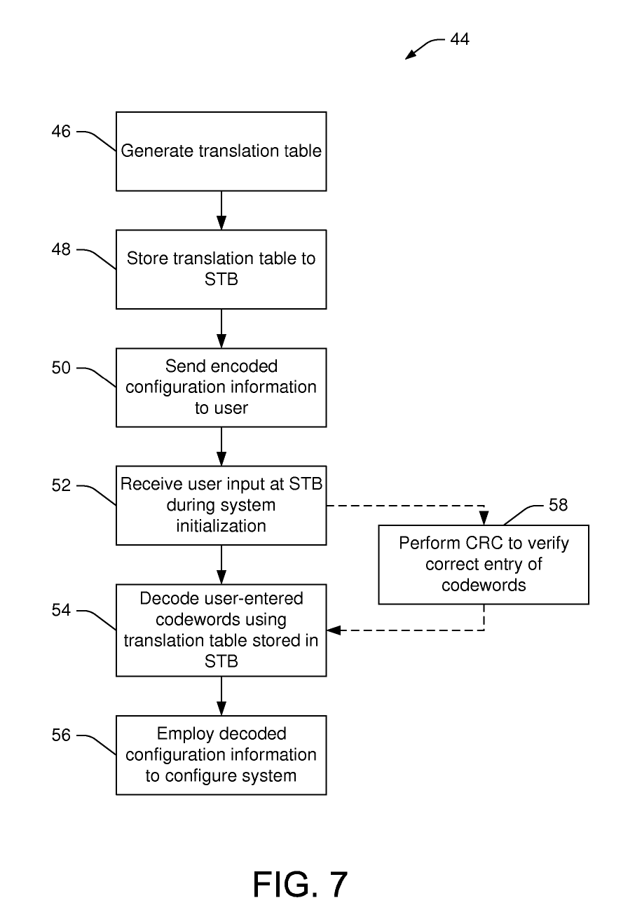

FIG. 7 illustrates a method of encoding and decoding configuration information to permit a user to configure an STB for a remote healthcare monitoring system in the user's home.

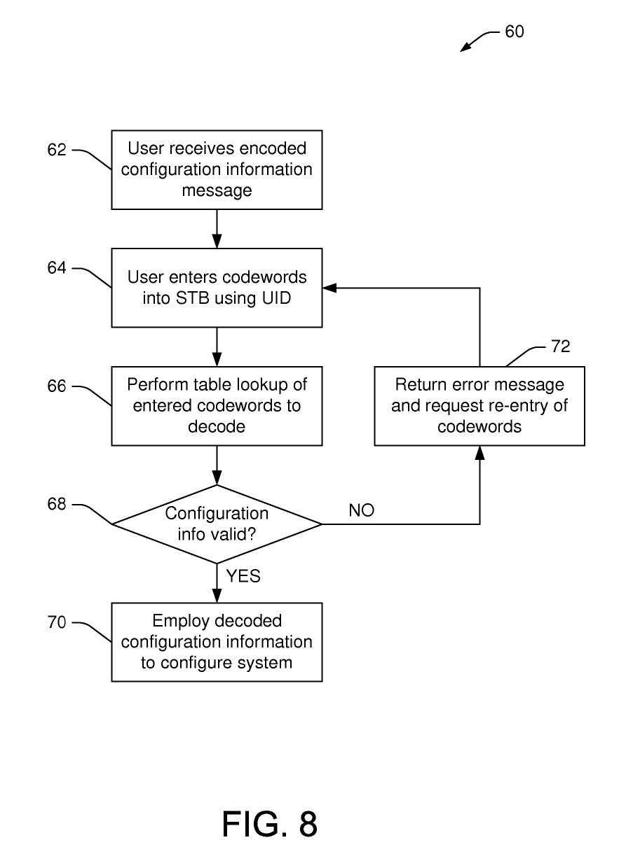

FIG. 8 illustrates a method of configuring a remote healthcare system that reduces system costs by permitting a user to enter encoded configuration information into the system while minimizing user actions and simplifying information entry.

A remote patient monitoring system 10 includes a device (STB 12), such as a set top box that communicates patient status information using an Ethernet component 14 to a centralized server 16 associated with a healthcare service provider. Although the STB is described as a being a set top box analogous to a cable television set top box, it is appreciated that the device can be built into a system that provides an interactive healthcare platform. According to some examples, the system employs broadband television and remote vital sign measurement devices to connect patients to their healthcare providers and/or medical support system. In this manner, care providers can customize an experience for each patient and can provide personalized, media-rich content to engage the patient and encourage healthy living, disease or illness management, or the like. For instance, the system may be employed to deliver educational material such as video-on-demand, with topics relevant the patient's healthcare needs. According to other examples, the system can be used to provide timely reminders to the patient to take medication, attend a doctor's appointment, etc. Still other system functions relate to providing feedback about patient vital signs and the like to help the patient track progress toward a personal goal, as well as to providing motivational messages to the patient. Health-related surveys can also be performed to test for patient comprehension and/or compliance, etc.

The STB 12 is configured during an initial installation and/or configuration protocol, during which patient-specific registration and configuration information is stored to the STB 12. In conventional systems, such configuration is performed by the service provider in a costly and laborious manner. That is, the STB is pre-configured for the patient prior to being set up in the patient's home or residence. In accordance with various features described herein, STB 12 configuration simplified and encapsulated in order to be performed in the patient's residence, by the patient, using an off-the-shelf generic STB 12 (e.g., an STB that need not be pre-configured).

FIG. 1 illustrates a remote care system 10 for configuring an STB 12 in a patient's residence, rather than pre-configuring the STB 12 at the service provider, and for providing a secure, personalized platform service that connects a remotely located patient to his or her care provider. The system 10 permits a healthcare organization to effectively and efficiently empower and assist a patient to manage a chronic disease or condition. The system 10 includes the STB 12, which has an Ethernet component 14 that permits the STB 12 to connect to a centralized service provider server 16 via the Internet. Additionally, the STB 12 is operatively coupled to a GIU 18 (e.g., a television set, a personal computer, a laptop, a tablet PC, etc.) through which information is presented to the patient, or “user,” and through which the user may enter information into the STB 12. In some embodiments, the STB 12 and the GUI 18 and related components are integral to one another. For instance, the STB 12 can be a laptop computer, a tablet PC, a desktop PC, a handled PC, a PDA, etc. The STB 12 further includes a processor 20 that executes computer-executable instructions, routines, algorithms, and the like, associated with performing the various actions and providing the various functions presented herein. A memory 22 stores information associated with STB function, configuration, user data, etc., and any other suitable information related to various functions of the system 10. The memory 22 comprises persistent memory, volatile memory, or any other suitable memory for performing the various actions described herein and for storing information related thereto. Moreover, the STB 12 includes wireless communication components, such as a Bluetooth component 24 and/or an infrared (IR) component 26 that communicate with a mobile phone 28. Additionally or alternatively, the STB 12 can employ other wireless communication technologies and/or components, such as a Zigbee, WiFi, or the like.

In FIG. 1, although the mobile phone 28 is depicted, it is to be understood that other suitable devices can be employed, such as a laptop, a tablet PC, a desktop PC, a PDA, an I-Phone™ or the like. Additionally, the user can enter information into the device using a keyboard, a stylus or other instrument for manipulating a touch screen computer or device, etc. If a computer is utilized, the computer may function as both the GUI 18 and the mobile phone 28. According to an example, the user receives an email message including coded user identification information and/or STB configuration information, which the user then forwards to the STB 12 via a link with the Bluetooth component 22, the IR component 24, cable, or by manually entering the information using a computer keyboard, mouse, or touch screen. According to other aspects, the user enters the information into the STB 12 via a remote control (not shown). For instance, the user can utilize number keys to enter numbers directly or arrow keys on the remote control to select a sequence of words, numbers, and/or graphical images on the GUI 18 that corresponds to the sequence of words, numbers and/or graphical images received in the message. Moreover, other methods of receiving the message include via telephone or voicemail, postal mail, via a website to which the user logs in, etc. By sending the message to a user-proved email address, street address, telephone number, and/or by requiring the user to log in to a secure website (e.g., with a user-selected password), the service provider can ensure that the user receiving the message is the intended user.

Alternately, the remote for the STB can be configured to interact with the telephone, cell phone, computer, or suitable devices as described above. If the user does not own a computer, cell phone, or the like, the remote can be brought to a location with such access to retrieve the information. As another option, the remote (or the STB) can be configured to hear, e.g., with a microphone, the frequency tones of a conventional touch-tone phone, translate the tones into alphanumerical digits, and transmit the decoded digits wirelessly to the STB. As another option, a separate installation module can be provided, e.g., sold or loaned, to those without cell phone or computer technology.

According to other features, a user provides his or her mobile phone number to the service provider at some point prior to system setup. When the user receives the off-the-shelf STB 12 and is ready to configure the STB 12 or to log on to the STB 12 for a remote monitoring session, a message is sent by a service provider to the user's mobile phone 28. In this manner, the service provider can ensure that the intended user is correctly identified because the user's mobile phone number serves as a verification of the user's identity. The message contains user-specific information, and is transmitted and received in the form of an encoded short message service (SMS) message, or text message. For instance, the user can receive a text message comprising a few words of text, where each word is associated with one or more numerical digits or values. For instance, each word (or symbol according to some aspects) can be associated with an integer value, a binary value, a hexadecimal value, etc. According to a simplified example, the user receives a text message comprising the words “one, six, three,” which respectively represent the values 1, 6, and 3. In this example, the user's identification number is 163, and such information is input into the STB 12 via forwarding from the mobile phone 28 to the STB 12 via the Bluetooth component 22 and/or the IR component 24. Alternatively, the user enters the numbers 1, 6, and 3 sequentially into the GUI 18 or the cell phone keypad.

According to another example, the message includes a sequence of words, each of which corresponds to one or more digits in the user's identification number, but do not explicitly describe a number. For instance, the message may comprise the sequence “cow cat dog moose,” which may correspond respectively (and arbitrarily for the purpose of this example) to the numbers 3, 5, 7, and 2. Thus, the user's ID number is 3572, although the user need not know or remember this number. The user then either forwards the message to the STB 12 or enters the message into the GUI 18. For instance, the user can select from a plurality of images presented to the user on the GUI 18 using a mouse, stylus, keyboard cursor arrow(s), etc., if the GUI 18 is a computer, or using arrows on a remote control if the GUI 18 is a television. In this example, the user selects an image of a cow, then and image of a cat, then a dog, and finally a moose. The processor 20 performs a table lookup routine on a translation table, or lookup table, to identify a numerical value associated with each word image to decode the user's ID number. The translation table is stored in the memory 22, as well as at the server 16, which encoded the message prior to sending to the user via the mobile phone 28, email, overnight courier, the post office, a standard phone call, or the like. In some aspects, it is desirable to use short words (e.g., approximately three to five letters in length) for the translation table, in order to minimize labor associated with user input, such as where user enters the word sequence using a keyboard.

According to other aspects the message is received as a multimedia message service (MMS) message, such as an image and/or audio file. In this case, the user can receive a sequence of shapes that can be entered via the GUI and decoded to ascertain a numerical sequence. Additionally, information received in message format by the user, whether email, voice mail, SMS, MMS, etc., is not limited to user ID information, but rather may comprise any suitable or desired configuration information, such as device ID information, IP address information, server ID information, etc.

Additionally, or more monitoring devices (not shown) can be coupled to the STB (e.g., via a wired connection and/or using one or both of the Bluetooth component and the IR component), and can monitor a status of the user or patient and provide status information to the STB, which in turn can provide the information to the server for review by a caregiver, physician, or the like. The monitoring device(s) may be, for instance, a blood pressure monitor, a digital scale, a blood-glucose monitor, a blood-oxygen monitor, a carbon-dioxide monitor, an electrocardiogram device, or any other suitable device or measuring or monitoring a health condition of the user.

FIG. 2 illustrates a system 30 for entering information received in a message from a service provider into the STB 12 using the GUI 18 and a remote control 32. Additionally, the GUI can include a touch screen monitor. In this sense, FIG. 2 shows a simple means by which a user enters information to the STB 12, after the user's identity has been confirmed by receiving the message at a user-provided address or phone number. That is, the service provider is ensured that the intended user has received the message because the message is sent to a user-approved or verified destination. The remote control 32 can be a generic remote control device or one customized to receive and reply to patient care content, has a plurality of buttons 34, including but not limited to a plurality of directional arrows that the user manipulates to navigate through the GUI 18, and an “Enter,” (e.g., or “select,” etc.) button that the user depresses to select a given graphical representation. The GUI 18 shows a number of graphical representations (e.g., numbers in this example) from which the user selects to input the information associated with the received message. As stated above, the message can be received via mobile phone or other mobile communication device, email, post, voicemail or telephone, etc. Additionally, although the images from which the user may select are depicted as having both a representation of the number itself and of the word for the number, both graphical depictions need not be presented to the user. Rather, the user may, according to some features, be presented with only the number or only the word representing the number.

In the simplistic example of FIG. 2, a user who has received a message (e.g., email, text, etc.) such as “four three seven” can navigate the GUI 18 and sequentially select the numbers 4, 3, and 7 using buttons 34. The information entered by the user can represent, for instance, a user ID number, a device ID number for configuring the remote care system and/or the STB 12, an IP address for connecting the STB 12 to the server 16, etc., or any other information for entry during system configuration and/or log-in. Thus, the service provider can send information to the user via one or more messages, and the user enters the information into the STB 12, when prompted (e.g., upon receiving the information) without necessarily being aware of the nature of the information. Additionally, the information in the messages can be encoded prior to transmission to the user, and decoded by the STB 12 upon entry by the user, as described in greater detail below.

FIG. 3 shows another embodiment of remote care system 36 for entering received information into the STB 12 using the GUI 18 and a remote control device 32, wherein codewords are presented on the GUI 18 for user selection. The GUI 18 includes multiple graphical representations of words, each of which corresponds to a numerical value comprising one or more digits. According to an example, a user receives a message, such as “My tree runs fast.” Because the message is sent to a specific address (e.g., phone number, email, etc.) provided by the user, the healthcare service provider is ensured that the data is sent to the intended user. The user then either forwards the message to the STB 12 using a wireless link such as Bluetooth or an IR link. Alternatively, the user can utilize the remote control 32 (or other input device depending on the GUI, such as a keyboard, stylus, voice-recognition software and a microphone, mouse, etc.) to select the sequence of words. For instance, the user can scroll to an icon of the word “My” and press the select button on the remote control 32, then scroll to “tree” and select, then to “runs,” and so on. The message can be a simple sentence, a string of words, or the like. With simple sentences, there can be separate screens for nouns, verbs, etc. Once the selected sequence is entered into the STB 12, it is decoded.

Decoding an entered sequence includes looking up each selected word in a data table and identifying its associated value. For instance, if each word is associated with a single digit value, then only ten words need be used to encode the message for sending to the user. Thus, a service provider-side server, such as server 16, can have stored thereon any and all configuration and/or user information that is to be employed during system configuration, and can encode a message for the user by identifying the digits the user is to enter during setup and generating a message with the words corresponding to the numerical sequence. Upon receipt, the user enters the codeword sequence into the STB 12 via the GUI 18, and the STB 12 performs a table lookup of a translation table stored in memory to decode the word sequence by identifying the sequence of numbers corresponding thereto. Optionally, a cyclic redundancy check protocol or other verification technique can be performed on the entered information for verification purposes. The STB 12 then employs the decoded information to configure itself and/or the system in which it is employed.

According to another example, each codeword corresponds to a two-digit numerical sequence (e.g., 13, 01, 49, etc.), in which case 100 codewords can be employed to represent the set of 100 two-digit sequences [00-99]. Accordingly, an ellipsis (three dots) is shown in the GUI 18 to represent that any number of codewords may be employed in conjunction with various aspects, as well as be presented to the user. In this case, the translation table becomes slightly larger with the benefit of reducing message size and the number of codewords to be entered by the user. For example, using a 100-codeword translation table, a 12-digit device ID number can be encoded, transmitted, and entered by the user with only six codewords. A 1000-codeword translation table (e.g., for the set of three-digit sequences [000-999]) permits the same 12-digit number to be encoded using only four codewords, and so on. Hexadecimal, alphanumeric, upper/lower case letters, octal, binary, and other counting schemes are contemplated. Indeed, any number of codewords may be employed to represent any number of N-digit numerical sequences, where N is an integer, and is only limited by design considerations regarding, for example, a point of diminishing returns with respect to an upper bound on the number of codewords or icons that a typical user will be able to successfully and quickly navigate through to complete configuration of the system. By reducing the number of codewords and/or icons to be selected on the GUI 18, user involvement is further minimized, thereby reducing the risk of user error and increasing the ease with which even the most infirm or otherwise disabled or inept user can configure the remote healthcare system.

FIG. 4 illustrates another embodiment of a system 38 for configuring the STB 12 using the GUI 18 and a remote control device 32, wherein codewords are represented by respective symbols on the GUI 18. By using symbols instead of words, the same messaging system can be utilized in any country for native speakers of any language because language has been removed from the interface, which in turn further simplifies configuration and reduces cost. For instance, the user may receive a message via mobile phone, email, text, post, telephone, voicemail, etc., comprising a sequence of codewords in the patient's preferred language. According to one example, the user receives an SMS text message on a mobile phone with a sequence of words, such as “sun moon star rain.” If the user is unable to forward the encoded message to the STB 12 (e.g., the user's mobile phone is not Bluetooth or IR enabled), then the user can enter utilize the remote control 32 to navigate through the GUI 18 and select the symbols corresponding to the codewords in the designated sequence. The corresponding numerical sequence is then determined by the STB 12 upon decoding of the entered symbol sequence. An ellipsis is illustrated on the GUI 18 to indicate that the system 38 is not limited to the 11 codeword symbols shown in FIG. 4, but rather may comprise any suitable or desired number of images. For instance, if each image corresponds to a single digit, then 10 symbols can be utilized. Additionally, if each symbol corresponds to a two-digit sequence, then 100 symbols can be employed, and so on.

According to another example, the user receives an MMS message via cell phone (e.g., or an email, post, etc., comprising images) having a plurality of symbols to be entered to the STB 12 for configuring the STB 12 and/or other system components. The user then navigates through the GUI 18 using the navigational arrows on the remote control 32, and sequentially selects the symbols received in the message. The STB 12 then executes a lookup routine to evaluate a translation table in a memory store and identifies the numerical sequences corresponding to the entered symbols to decode the information sent in the message. In this manner, a user can employ elementary word and/or picture recognition skills to enter otherwise complex configuration code and/or user information into the STB 12.

In accordance with other features, the STB 12 can execute peripheral verification routines, such as a cyclic redundancy check (CRC) protocol, to ensure that the information has been correctly entered by the user. Moreover, one or more symbols and/or codewords can represent punctuation (e.g., periods, commas, back-slash, forward-slash, etc.) and/or other symbols to facilitate correct decoding of the information. For instance, a particular codeword or symbol can be associated with a period (.) for insertion between other codewords or symbols to delineate where the period should be inserted when decoding the message, such as for information describing an IP address, a subnet mask, or the like.

According to yet another example, a user can utilize the remote control 32 and GUI 18 to confirm information for the STB 12 and/or the server 16 in response to a query by the server 16, such as during configuration and/or troubleshooting. For instance, a series of symbols and/or codewords corresponding to numerical sequences (e.g., model number, serial number, software version number, etc.) associated with the STB 12 can be placed on the STB 12 when it is manufactured or loaded into its software or memory during or after configuration. If a need arises for the user to enter such information via the STB 12, the user can be prompted to do so. According to a specific example, the user can be presented with a series of symbols and/or codewords on the GUI 18 and asked to verify whether the series of symbols on the GUI 18 matches the series of symbols printed on the STB 12 to permit the service provider server and/or server-side technician to verify such information. Still other examples relate to employing codewords and/or symbols at a later time to log in to the system or the like. Symbols can additionally have variants, such as a white circle and a shaded circle, or the like. In this manner, the user only enters a simple yes or no response to provide the desired information. During troubleshooting, error codes can be reported to the user in the form of a series of graphical symbols or words.

FIG. 5 is an example of a translation table 40, such as can be utilized to encode messages for a user and/or to decode messages entered and/or forwarded to the STB by the user. The translation table 40 has two columns: the left column includes numerical values, each of which is associated with a codeword in the right column. Although table 40 depicts each number as corresponding to the word that describes it, any word can be utilized, as described above. For instance, the right column can comprise a noun for each number (e.g., car, pipe, log, hat, spoon, ant, soda, bear, mule, lake, etc.). Although codewords are not limited to being nouns, nouns are convenient when displaying user-selectable images to the user for entry of the codewords. Additionally, care may be taken when designing the translation table 40 and assigning codewords to ensure that codewords are sufficiently different from one another to permit a user with poor eyesight to distinguish there between. For instance, since most mobile phones do not permit text size to be adjusted, it may be desirable to avoid employing “car” or “rat” in the same translation table as “cat.” It may also be desirable to avoid homonyms and words with two or more divergent meanings or regional, generation-related, religious, differing, or offensive connotations. In this manner, user confusion and/or error can be mitigated.

FIG. 6 shows a more complex translation table 42, which can be utilized as a codec to encode and/or decode messages by identifying codewords and their corresponding numerical sequences. For instance, the left column of the table 42 includes a set of 100 two-digit numerical sequences (e.g., the inclusive set [0-99]). The right column of the translation table includes corresponding codeword for each numerical sequence. The codewords in FIG. 6 are arbitrarily selected for purposes of this example, and are not to be construed in a limiting sense. Rather, any suitable codeword may be assigned to or associated with any numerical sequence.

For example, when constructing a message for a user, a server-side message generator (e.g., a server, technician, etc.) can determine that the user needs to enter the numerical sequence: 1335355812. The numerical sequence is encoded using the translation table 42 (e.g., by a processor that executes a routine to perform the table lookup and output the encoded sequence), and the encoded message “mouse apple apple egg ape” is then provided to the user. The user can then enter the encoded message to an STB, such as the STB 12 described above, at the user's residence by selecting the codewords themselves or symbols representing the codewords on the GUI. The STB then decodes the entered message by performing another table lookup (e.g., a reverse lookup) to decode the codeword sequence back into its original numerical sequence form, and employs the numerical sequence to configure itself and/or other remote health care system components.

FIGS. 7-8 illustrate one or more methods related to installing and/or configuring a remote health monitoring system by a patient, in accordance with various features. While the methods are described as a series of acts, it will be understood that not all acts may be required to achieve the described goals and/or outcomes, and that some acts may, in accordance with certain aspects, be performed in an order different that the specific orders described.

FIG. 7 illustrates a method 44 of encoding and decoding configuration information to permit a user to configure an STB for a remote healthcare monitoring system in the user's home. At 46, a codec, or translation table, is generated. The codec table includes a plurality of numerical sequences and corresponding words representing respective numerical sequences. Optionally, the codec table is generated using a randomizer or the like, for increased security and product matching, etc. At 48, the codec table is stored to the STB. For instance, during manufacture, by inserting a portable memory element, by downloading from a public Internet site, or the like, the codec table can be stored in memory in multiple STBs, so that a number of STBs can be generically produced without specific knowledge of the ultimate user. The codec table is also provided to a healthcare service provider or configuration provider server, in order to permit the provider server and STB communicate.

At 50, an encoded message is sent to the user. The message includes configuration information for the user's STB, which includes without being limited to user ID information, IP addresses, network ID information, and any other information the user may be prompted to enter to during setup of the STB and healthcare monitoring network. For example, the message can contain an encrypted user ID that the user enters to log onto the system. In this case, a ten-digit user ID, and possibly additional or longer numbers that are entered during configuration, may be a daunting entry to a user who is infirm, elderly, arthritic, etc. To make entry of the user ID information easier, the encoded user ID is sent to a user-specific device, such as a cell phone or email address, or by regular mail that the user has provided to the healthcare service. Because the user has provided the address or phone number, the provider is assured that the intended user is the recipient of the encoded message, and not some other person. Because the message is encoded as a sequence of short words, the message appears as nonsense to any recipient who is not the intended recipient (e.g., a patient employing the remote monitoring system).

At 52, the encoded message is relayed to the STB during an initialization period (e.g., setup, login, etc.). The user can input the encoded message in a variety of ways. For example, the user's mobile phone and/or computer (e.g., laptop, PC, tablet, etc.) is Bluetooth or IR enabled, then the user simply forwards the encoded message to the STB, where it is decoded using a reverse lookup routine and the same codec table that was used to encode the message. If the user device at which the message is received is not able to forward the message, then the user enters the message manually, such as by typing the message into a keyboard associated with a GUI of the STB, using a mouse, a stylus, a remote control to select words or images on a screen on the GUI, etc. Once entered, the STB decodes the message back into its original numerical sequence, at 54. The decoded sequence is then utilized to configure the system, at 56. For example, if the sequence represents the user's ID number, then upon entry and decoding, the user can be permitting to access the STB and related system. If desired, at 58 a cyclic redundancy check (CRC) protocol is performed to confirm correct entry of the codewords. Of course, in the embodiments of FIGS. 1 and 2, and in other embodiments in which the numbers are entered directly, no codec (or no coded beyond a decimal-to-binary converter) need be generated, stored, or used for decoding.

FIG. 8 illustrates a method 60 of configuring a remote healthcare system that reduces system costs by permitting a user to enter encoded configuration information into the system while minimizing user actions and simplifying information entry. For instance, at 62, a user receives an encoded configuration information message. According to one example, the user receives the configuration message as a text message on a cell phone. In this example, the user has provided the cell phone number to the healthcare provider sending the message, so the healthcare provider is assured that the user to whom the message is sent is the intended recipient. Optionally, the user can answer questions to the provider to verify identity or differentiate between multiple users of a single STB. Alternatively, the user can receive the configuration message at a pre-provided email address, as well as by post, voicemail, or in any other suitable manner. The configuration message contains a plurality of codewords, each of which corresponds to a specific numerical sequence (e.g., one or more integers, hexadecimal values, etc.).

At 64, the user enters the configuration codewords into an STB using a user input device (UID). The UID can be, for instance, a keyboard associated with the STB or with a computer associated with the STB. According to other examples, the UID is keyboard, a mouse, a stylus, or some other input device associated with the computer at which the configuration email message was received. If the users computer or cell phone is enabled for Bluetooth or IR communication, then the user simply forwards the received message (e.g., email, text, SMS, etc.) to the STB, which is Bluetooth and IR enabled. In this case the cell phone or computer acts as the UID and user involvement is minimized. If the UID is not Bluetooth or IR enabled, then the user manually enters the information into the STB, using the above-mentioned keyboard, stylus, or mouse, voice-activated software, or the like. In some examples, the user utilizes a remote control to scroll through and select the codewords and/or images, as previously described.

According to another example, the user is presented with information related to the codewords received in the configuration message via a GUI (e.g., a computer screen, a television, etc.) connected to the STB. For instance, the user can be presented with a plurality of words (e.g., text) on the GUI screen, and can select words in the screen using the UID, in the sequence in which they appear in the configuration message. According to another example, the user is presented with images corresponding to various codewords, and sequentially selects the images corresponding to the codeword sequence in the received message. For instance, if the user receives a text message reading “cow cat dog tree ape,” then the user can serially select the corresponding words and/or images on the GUI using the UID. Moreover, according to other aspects, the user can be permitted to select whether the GUI presents images or words, or both, depending on the user's preferences. In this manner, the user is isolated from complicated entry of lengthy configuration code sequences, user ID numbers, and the like, which can be difficult for users with poor eyesight, the elderly, the infirm, etc.

At 66, the STB performs a table lookup of the entered codewords and translates the codewords into the numerical sequence represented thereby. For instance, if each codeword represents a two-digit number between 0 an 99, then the five-codeword sequence “cow cat dog tree ape” is translated into a 10-digit numerical sequence that the STB can recognize as a configuration code (e.g., a network ID, a user ID, or some other suitable configuration code, etc.). The STB thus decodes the encoded configuration message entered by the user.

At 68, a determination is made regarding whether the configuration information is valid. The determination can be a function of a CRC protocol performed on the entered sequence, for example. If the entered configuration is valid, then at 70 the decoded configuration information is employed to configure the STB and/or the remote healthcare system associated with the STB (e.g., one or more monitoring devices, such as a scale, a blood pressure cuff, etc.) If the information entered is not valid, then at 72 an error message is presented to the user (e.g., via the GUI) along with a prompt to re-enter the codewords. In this manner, user entry of complicated configuration information and/or lengthy numerical sequences can be made easier by permitting the user to enter simple codewords and/or related images. In other examples, the user simply forwards a received codeword message using Bluetooth or IR communication techniques, such that user entry of the configuration information is completely reduced to a single forwarding action.

As another alternative, an Ethernet-enabled STB receives less than all configuration information as described above. Rather, the user receives enough information to connect with, and identify itself to, the server, and receives the remaining configuration information from the server. Additionally, the STB can be pre-loaded with several configuration routines, and the configuration information described above can include an identification of which routine to execute. For example, the STB can be pre-loaded with the IP addresses of 100 (e.g., [00-99]) setup configuration servers for each of 100 different countries or regions, enabling the IP addresses to be entered, in most cases, with two decimal digits.

1. A system (10) for configuring a remote healthcare system using encoded configuration messages, including:
a first device (12) that requires entry of encoded configuration information to be functional; and
a second device (18, 24, 26, 28, 32) that either enters the configuration information directly or presents the configuration information as codewords or symbols.

2. The system according to claim 1, further comprising memory that receives and stores audio and video data for presenting interactive wellness and health-education programming to a user.

3. The system according to claim 1, wherein the first device (12) includes a component (24, 26) that receives the user-entered encoded configuration information.

4. The system according to claim 3, further comprising communication device (28) on which the user receives the encoded configuration information, wherein the communication device (28) is at least one of a cellular phone, a personal desktop assistant, a laptop, or a personal computer, and has a component with wireless communication capability.

5. The system according to claim 1, further comprising a translation table (40, 42) that stores a plurality of codewords and corresponding numerical sequences for decoding the encoded configuration information, and a graphical user interface (GUI) (18) that presents information related to system configuration to the user.

6. The system according to claim 5, wherein the user receives the encoded configuration information as a series of codewords in at least one of a voice, image, or text message on a communication device (28).

7. The system according to claim 6, wherein the communication device (28) is at least one of a cellular phone, a personal desktop assistant, a laptop, or a personal computer, and has at least one of Bluetooth or infrared communication capability, wherein the user enters the encoded configuration information into the first device (12) by forwarding the received message to the first device (12) using at least one of a Bluetooth communication link or an infrared communication link, and wherein the first device (12) decodes the forwarded message by performing a table lookup on the translation table (40, 42) and determines the numerical sequence corresponding to each codeword in the message.

8. The system according to claim 6, wherein the user enters the encoded configuration information into the first device (12) using a user input device.

9. The system according to claim 8, wherein the user input device includes a remote control configured for the user to sequentially select the codewords in the message from a plurality of codewords displayed on the GUI (18) using navigational arrow buttons on the remote control (32).

10. The system according to claim 8, wherein the user sequentially selects the codewords in the text message from a plurality of corresponding icons or images displayed on the GUI (18) using navigational arrow buttons on the remote control (32).

11. The system according to claim 5, wherein the translation table (40, 42) is generated using a randomization technique.

12. The system according to claim 1, wherein the first device (12) includes:
a routine or means (54) for performing a table lookup on the translation table (40, 42) to decode user-entered codewords;
a routine or means (56) for configuring the system (10) using the decoded configuration information; and
a routine or means (58) for selectively performing a cyclic redundancy check protocol that verifies that the user-entered codewords are correctly entered.

13. A method of configuring the system (10) of claim 1, including:
generating the translation table (40, 42) by assigning a codeword to one or more of a plurality of numerical sequences;
storing the translation table (40, 42) to the first device (12);
prompting a user to enter a plurality of codewords by selecting images corresponding to the codewords;
decoding the entered codewords to identify respective numerical sequences; and
employing the numerical sequences to configure the system (10).

14. A method for configuring the system (10) of claim 1, including:
transmitting a configuration message comprising codewords representing encoded configuration information to a user device;
presenting a plurality of at least one of images, words, and numbers to a user;
prompting the user to enter the codewords in the configuration message by sequentially selecting the codewords, from the plurality of at least one of images, words, and numbers;
decoding entered codewords to identify the configuration information; and
configuring the system (10) using the decoded configuration information.

15. The system according to claim 1, wherein the first device (12) is at least one of a laptop computer, a desktop PC, a tablet PC, a handheld PC, and a PDA.

16. A method for configuring a remote healthcare system, comprising:
receiving encoded configuration information in an encoded configuration message at a first device (12); and
using a second device (18, 24, 26, 28, 32) to enter the configuration information directly into the first device (12) via a wireless communication link or to present the encoded configuration information as codewords or symbols for manual entry into the first device (12).

17. The method according to claim 16, further including:
generating a translation table (40, 42) that pairs numerical sequences to codewords;
storing the translation table (40, 42) to the first device (12);
sending a text or image message to a user, wherein the text message includes a sequence of codewords;
prompting the user to enter the sequence of codewords into the first device (12);
decoding the codewords using the translation table (40, 42) to identify respective numerical sequences; and
employing the numerical sequences to configure at least one of the first device (12) and the system (10).

18. The method according to claim 17, further including presenting a plurality of images to the user via a GUI (18), wherein each image corresponds uniquely to a codeword.

19. The method according to claim 18, wherein the user sequentially selects images corresponding to the sequence of codewords in the text or image message.

20. The method according to claim 19, wherein the GUI (18) is a television coupled to the first device (12) and the user selects the images using a remote control (32), or a screen on a computer coupled to the first device (12) and the user selects the images using at least one of a keyboard, a stylus, a mouse, or a touch-screen.

21. The method according to claim 17, further including generating the translation table (40, 42) using a randomization technique.

22. The method according to claim 17, further including sending the text or image message to at least one of an email address and a cellular phone number provided by the user, or by mail or courier.

23. The method according to claim 22, wherein the user forwards the text or image message to the first device (12) using a wireless communication link, such as Bluetooth or infrared, to enter the sequence of codewords into the first device (12).

24. The method according to claim 23, further including executing a cyclic redundancy check protocol to determine whether the user-entered codewords are valid.

25. A processor (20) or computer medium (22) programmed to perform the method of claim 16.

26. A system for configuring a set top box (STB), including:
means (28) for receiving an encoded configuration message;
means (16, 28, 32) for entering codewords contained in the configuration message into the STB (12);
means (40, 42) for decoding the codewords and determining a numerical sequence represented by the codewords; and
means (20) for configuring the STB (12) using the numerical sequence.

27. The system according to claim 26, wherein the codewords are graphical symbols, and wherein the user is presented with a plurality of graphical symbols from which to select using the means (16, 28, 32) for entering codewords.
